(19) United States
(12) Patent Application Publication
(10) Pub. No.: US 2021/0075169 A1
(43) Pub. Date: Mar. 11, 2021

(54) SOCKET FOR ELECTRIC COMPONENT

(71) Applicant: ENPLAS CORPORATION, Kawaguchi-shi, Saitama (JP)

(72) Inventors: Ryota Toyama, Kawaguchi-shi (JP); Katsuya Tsuneoka, Kawaguchi-shi, Saitama (JP)

(73) Assignee: ENPLAS CORPORATION, Kawaguchi-shi, Saitama (JP)

(21) Appl. No.: 16/771,939

(22) PCT Filed: Dec. 13, 2018
(86) PCT No.: PCT/JP2018/045829

§ 371 Date: Jun. 11, 2020

(30) Foreign Application Priority Data
Dec. 25, 2017 (JP) 2017-248412

(51) Int. Cl. H01R 33/76; G01R 31/28

(52) U.S. Cl. CPC H01R 33/7664; H01R 2201/20; G01R 31/2863

(57) ABSTRACT

An IC socket incudes a socket body having a housing portion for accommodating an IC package; a contact pin electrically connected to a solder ball of the IC package; an operating member provided movably up and down on the socket body; and a pad which is opened and closed by an up and down movement of the operating member and covers an upper side of the IC package in a closed state. The housing portion is provided with an annular portion surrounding a side periphery of an accommodating area of the IC package, an accommodating space for the electric component is formed when the pad is closed and abuts the annular portion, and the pad is configured to be spaced upwardly from an upper surface of the IC package which is accommodated in the accommodating space when the pad is closed and abuts the annular portion.

### TECHNICAL FIELD

This invention relates to a socket for electrical component that is electrically connected to an electrical component such as a semiconductor device (hereinafter referred to as an “IC package”).

### BACKGROUND ART

Conventionally, an IC socket in which contact pins are disposed is known as this type of a socket for electrical component. The IC socket is disposed on a wiring substrate and the IC package to be inspected is accommodated, so that the terminals of the IC package and the electrodes of the wiring substrate are electrically connected through the contact pins to conduct tests such as electrical continuity tests.

Such an IC socket is known to be of the so-called open-top type which is open above the socket and which is configured to take in and take out the IC package from above the socket. (See, e.g., Patent Document 1).

### PRIOR ART DOCUMENT

### Patent Document

[Patent Document 1] Japanese Patent Application Publication No. 2006-127936

### SUMMARY OF INVENTION

### Problems to be Solved by the Invention

However, in an open-top type IC socket such as Patent Document 1, when an IC package, which, for example, extremely dislikes adherence of foreign matter on an upper surface of the package, is housed, it is inevitable that foreign matter adheres to the upper surface of the IC package because the IC socket is the open-top type.

Accordingly, the object of the present invention is to provide a socket (IC socket) for electrical component that can make it difficult to attach foreign matter to the upper surface of an electrical component (IC package) even in an open-top type.

### Means For Solving Problems

In order to achieve such a problem, the invention of claim 1 is characterized in that a socket for electrical component comprising: a socket body having a housing portion for accommodating an electrical component; a contact pin configured to be electrically connected to a terminal of the electrical component; an operating member provided movably up and down on the socket body; and a pad which is opened and closed by an up and down movement of the operating member and covers an upper side of the electrical component in a closed state,
wherein the housing portion is provided with an annular portion surrounding a side periphery of an accommodating area for the electrical component,
an accommodating space, which is configured to be closed in the housing portion, for the electric component is formed when the pad is closed and abuts the annular portion, and
the pad is configured to be spaced upwardly from an upper surface of the electrical component that which is accommodated in the accommodating space when the pad is closed and abuts the annular portion.

The socket for electrical component according to claim 2, in addition to the invention according to claim 1, is characterized in that the annular portion is a part of a guide member which is provided in the socket body for guiding the electrical component to the accommodating area.

The socket for electrical component according to claim 3, in addition to the invention according to claim 1, is characterized in that a cover unit having an arm rotatably supported on the socket body is provided, and the pad is rotatably supported on the arm.

The socket for electrical component according to claim 4, in addition to the invention according to claim 3, is characterized in that the cover unit places the pad outwardly above the accommodating area by making a back surface of the pad abut with the socket body or the operating member.

The socket for electrical component according to claim 5, in addition to the inventions according to claim 1, is characterized in that the contact pin is opened and closed by the up and down movement of the operating member.

The socket for electrical component according to claim 6, in addition to the invention according to claim 1, is characterized in that a plurality of the pads which open and close in different directions each other are provided, and the accommodating space is closed when the plurality of the pads are closed and abut the annular portion.

### Effect of Invention

According to the invention of claim 1, the housing portion for an electrical component is provided with an annular portion surrounding a side periphery of an accommodating area, and an accommodating space, which is configured to be closed in the housing portion, is formed when the pad is closed and abuts the annular portion. Therefore, when the electrical component is housed in the socket for electrical component and used, it is possible to prevent foreign matter from being attached to the upper surface of the electrical component if the electrical component is accommodated in the accommodating space and the pad is closed.

According to the invention of claim 2, since the annular portion is a part of a guide member which guides the electrical component to the accommodating area, it is not necessary to construct the annular portion by further another member, so that the structure of the socket for electrical component which has the pad to form the accommodating space can be simplified.

According to the invention of claim 3, a cover unit having an arm rotatably supported on the socket body is provided, and the pad is rotatably supported on the arm. Therefore, the pad can be moved by rotating the arm with respect to the socket body, and further the pad can be rotated more than the rotation angle of the arm by rotating the pad with respect to the arm, so that it is easy to open broadly the upper part above the accommodating area provided in the housing portion.

According to the invention of claim 4, since the cover unit places the pad outwardly above the accommodating area by making a back surface of the pad abut with the socket body or the operating member, the structure for opening and closing the pad securely by rotating the pad with respect to the arm can be provided compactly. Accordingly, the cover unit that is easier to open wider above the accommodating area of the housing portion can be configured in less space above the socket body of the socket for electrical component of an open-top type.

According to the invention of claim 5, since the contact pin is opened and closed by the up and down movement of the operating member, the opening and closing of the accommodating space by the pad can be linked with the opening and closing of the contact pin. Accordingly, while the electrical component is accommodated in the accommodating space and connected to the contact pin, the accommodating space can be securely closed, and foreign matter can be securely difficult to be attached to the electrical component during use of the socket for electrical component.

According to the invention of claim 6, a plurality of the pads which open and close in different directions each other are provided, and the accommodating space is closed when the plurality of the pads are closed and abut the annular portion. Accordingly, the operating range of each pad can be reduced and the opening and closing can be easily made, and the electrical components can be easily taken in and taken out.

### BRIEF DESCRIPTION OF DRAWINGS

FIG. 1 is a plan view illustrating the opening state of the IC socket according to the embodiment 1 of the present invention.

FIG. 2 is a side view illustrating the closed state of the IC socket according to the embodiment 1 of the present invention.

FIG. 3 is a partial cross-sectional perspective view illustrating the opening state of the IC socket according to the embodiment 1 of the present invention.

FIG. 4 is a cross-sectional view illustrating the open state of the IC socket according to the embodiment 1 of the present invention.

FIG. 5 is a partial cross-sectional perspective view illustrating the closed state of the IC socket according to the embodiment 1 of the present invention.

FIG. 6 is a cross-sectional view illustrating the closed state of the IC socket according to the embodiment 1 of the present invention.

FIG. 7 is a perspective view illustrating a contact pin of the IC socket according to the embodiment 1 of the present invention.

FIG. 8 is an explanatory view illustrating the operation of the upper end portion of the contact pin of the IC socket according to the embodiment 1 of the present invention, wherein (a) is in the closed state and (b) is in the open state.

FIG. 9 is a perspective view illustrating a guide member of the IC socket according to the embodiment 1 of the present invention.

FIG. 10 is a cross-sectional view illustrating the guide member of the IC socket according to the embodiment 1 of the present invention.

FIG. 11 is a perspective view illustrating an arm of a cover unit of the IC socket according to the embodiment 1 of the present invention.

FIG. 12 is a cross-sectional view illustrating the arm of the cover unit of the IC socket according to the embodiment 1 of the present invention.

FIG. 13 is a plan view illustrating the arm of the cover unit of the IC socket according to the embodiment 1 of the present invention.

FIG. 14 is a perspective view illustrating the front side of the pad of the cover unit of the IC socket according to the embodiment 1 of the present invention.

FIG. 15 is a perspective view illustrating the back side of the pad of the cover unit of the IC socket according to the embodiment 1 of the present invention.

FIG. 16 is a cross-sectional view in the diagonal direction of the IC socket according to the embodiment 1, wherein (a) is in the open state and (b) is in the closed state.

FIG. 17 is a side view illustrating an example of an IC package contained in the IC socket according to the embodiment 1 of the present invention.

FIG. 18 is a perspective view illustrating the opening state in the IC socket according to the embodiment 2 of the present invention.

FIG. 19 is a perspective view illustrating the closed state in an IC socket according to the embodiment 2 of the present invention.

FIG. 20 is a partial enlarged cross-sectional view illustrating the contact state of the tip portion of a pair of pads in the closed state of the IC socket according to the embodiment 2 of the present invention.

FIG. 21 is a partial enlarged cross-sectional view illustrating the contact state of the tip portion of a pair of pads in the closed state of the IC socket according to a modification of the embodiment 2 of the present invention.

### EMBODIMENT OF INVENTION

Hereinafter, embodiments of the present invention will be described.

### [Embodiment 1 of Invention]

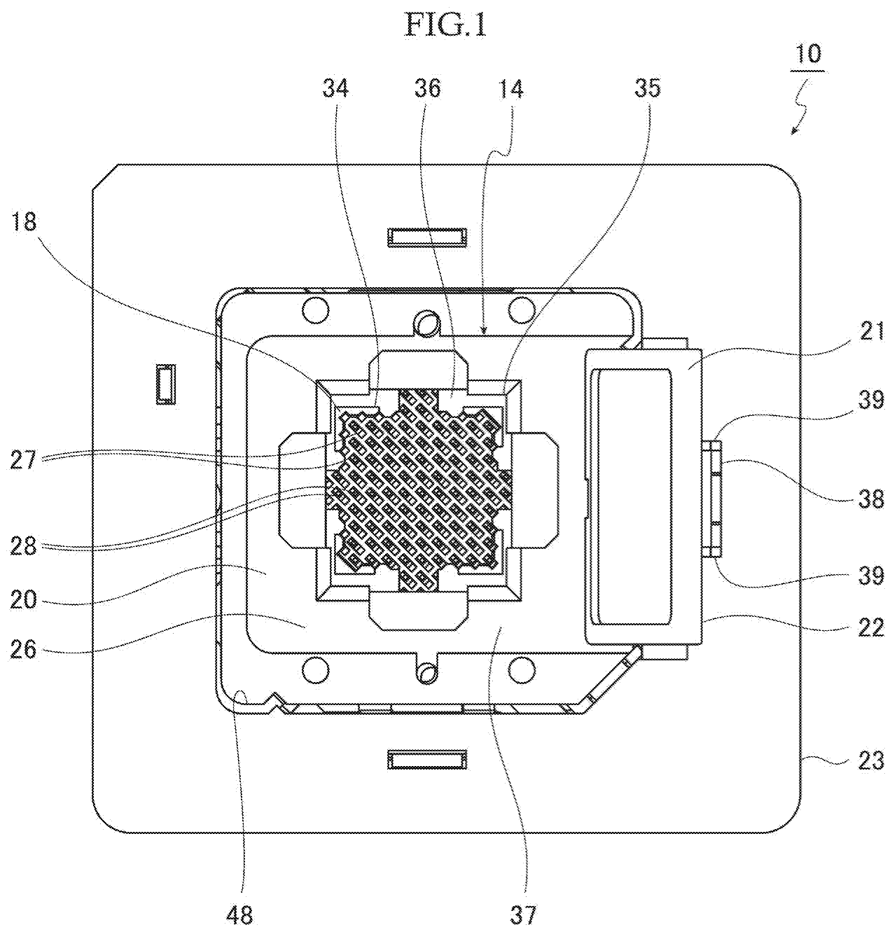

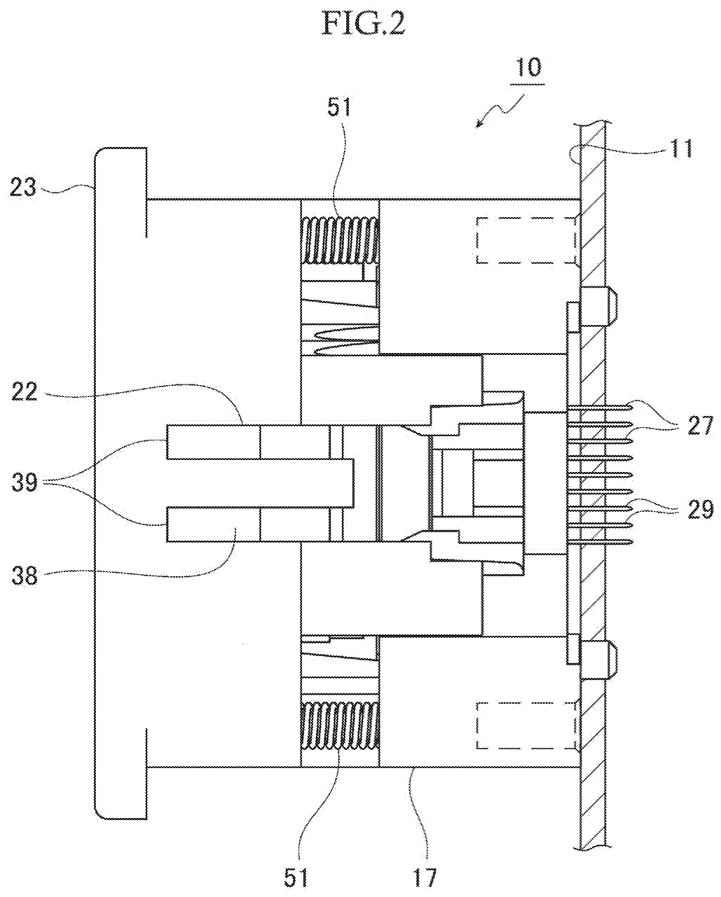

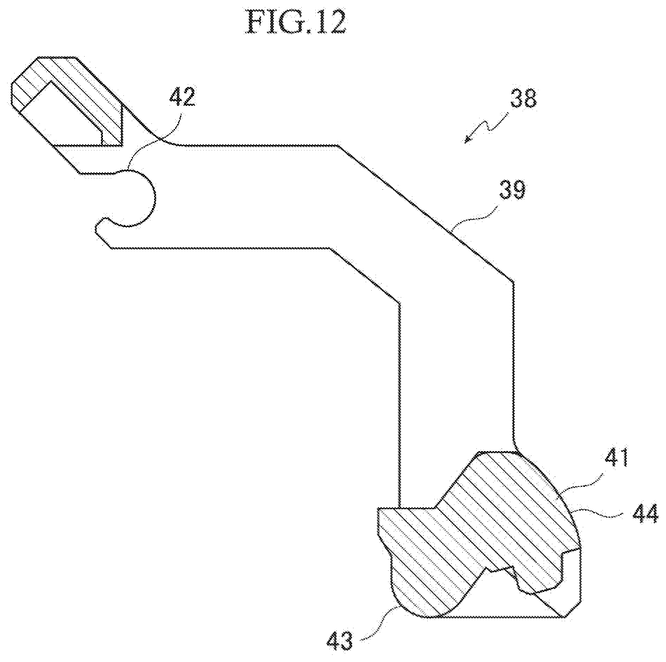

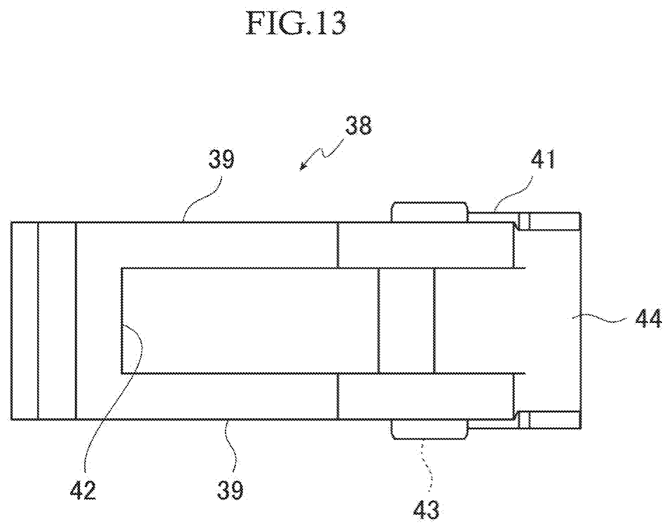

FIGS. 1-16 show the embodiment 1 of the present invention.

The IC socket 10 as a “socket for electrical component” of this embodiment has a housing portion 14 disposed on the wiring substrate 11 and containing the IC package 12 as an “electrical component” on the upper surface as shown in FIGS. 1-3, and is configured to electrically connect both the solder ball 13 as a “terminal” of the IC package 12 and the electrodes (not shown) of the wiring substrate 11. The IC socket 10 may be used, for example, in a test device for electrical continuity testing, such as a burn-in test for the IC package 12.

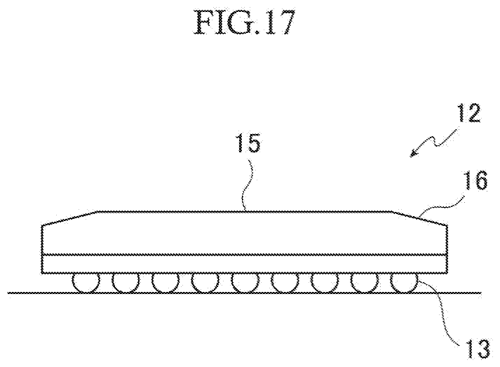

The IC package 12 of this embodiment is formed in a substantially square-shaped plate-like shape. As shown in FIG. 17, the upper surface is provided with an image sensor 15 and an inclined surface 16 surrounding it, and the lower surface is provided with a plurality of spherical solder balls 13 in a matrix-like shape within a predetermined range of a substantially rectangular shape.

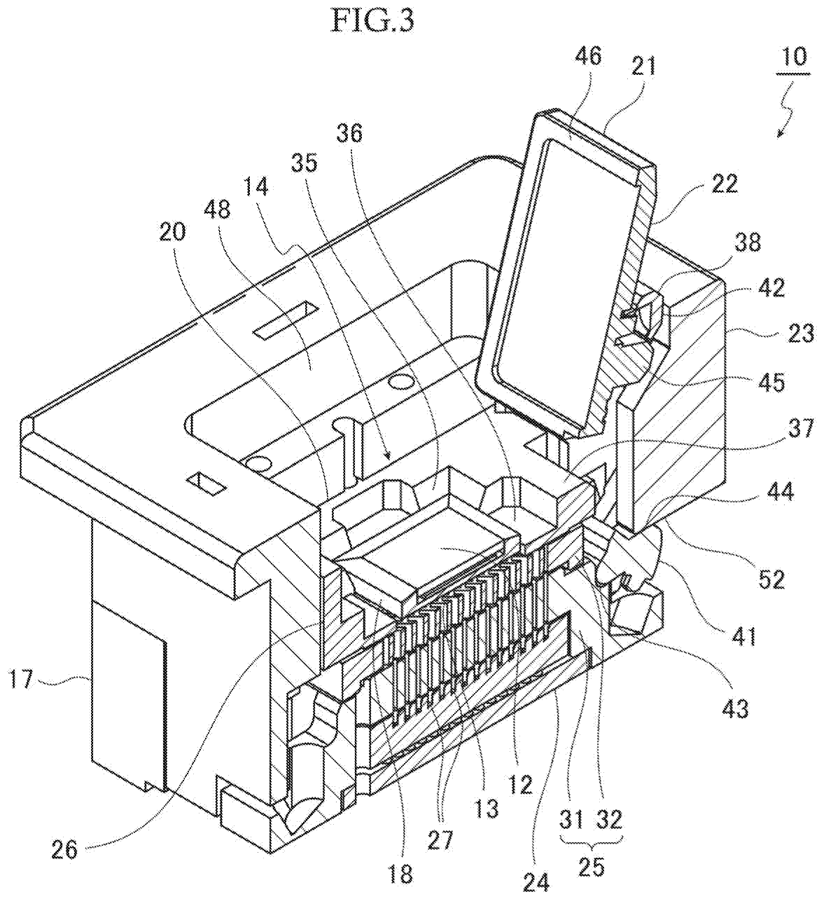

The IC socket 10 includes a socket body 17 which has a housing portion 14 disposed on the wiring substrate 11 to accommodate the IC package 12, as shown in FIGS. 3-6. The housing portion 14 includes an accommodating area 18, in which the IC package 12 is accommodated, and an annular portion 20 surrounding the accommodating area 18. The socket body 17 is provided with a cover unit 22 having a pad 21 which is able to open and close and to cover the upper side of the IC package 12 and an operating member 23 for opening and closing the pad 21.

Specifically, the socket body 17 exhibits a substantially rectangular shape in planar view and, as shown in FIGS. 3-6, a contact module 25 is disposed above the base portion 24, a housing portion 14 for accommodating the IC package 12 is disposed above the contact module 25, and a guide member 26 is disposed. A plurality of contact pins 27 are provided passing through the contact module 25 and the base portion 24.

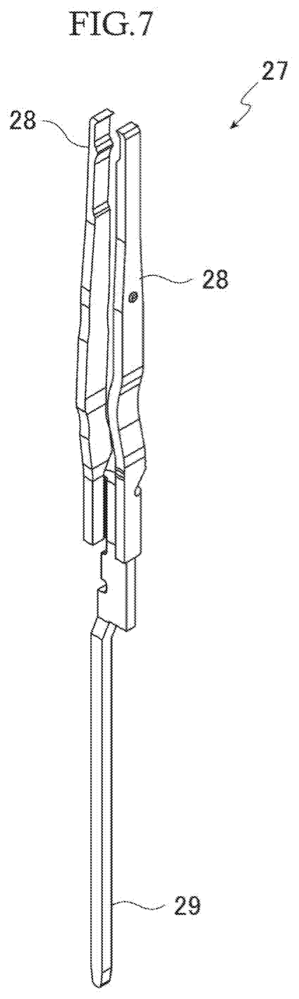

As shown in FIG. 7, the contact pin 27 is provided with a pair of clip pieces 28 facing each other at the upper end and a contact portion 29 to be connected to the electrode of the wiring substrate 11 at the lower end. The pair of clip pieces 28 can be spaced apart by elasticity, and the solder ball 13 of the IC package 12 accommodated in the housing portion 14 is griped by elasticity from the side and electrically connected with the wiring substrate 11.

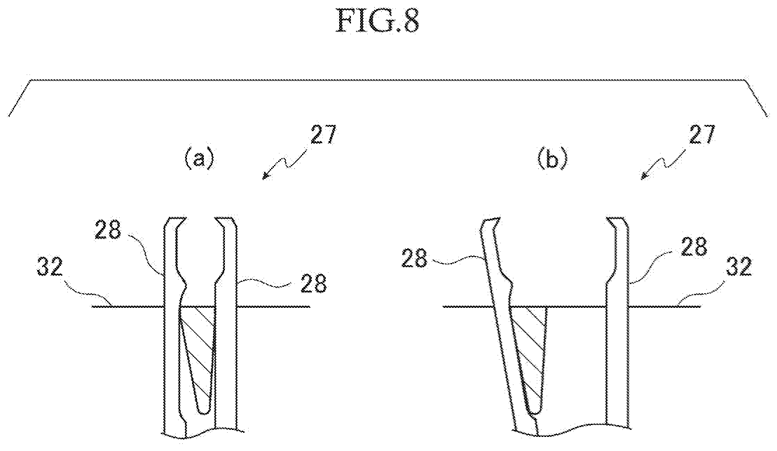

As shown in FIGS. 3-6, the contact module 25 includes a fixing block 31 and a slide plate 32 that can slide laterally relative to the fixing block 31. The slide plate 32, as shown in FIG. 8(a),(b), locks one clip piece 28 of each contact pin 27 and is configured to open and close the opposite clip piece 28 by sliding the slide plate 32 relative to the fixing block 31.

The housing portion 14 of the socket body 17 is provided with an accommodating area 18 for the IC package 12. In the accommodating area 18, the upper ends of the plurality of contact pins 27 are disposed to be positioned to correspond to the solder balls 13 of the IC package 12.

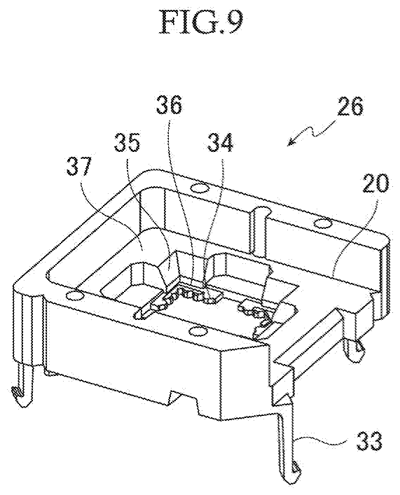

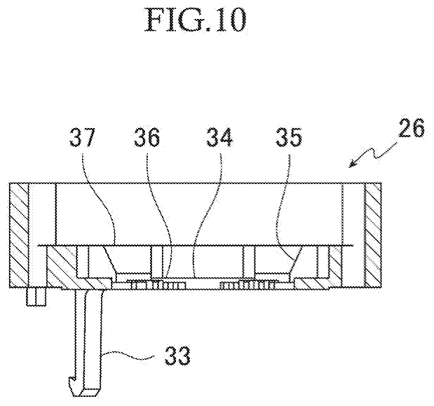

In this embodiment, a guide member 26 as shown in FIGS. 9 and 10 is disposed around the side of the accommodating area 18, and the guide member 26 is detachably fixed to the base portion 24, the contact module 25, or the like by a locking protrusion 33 or the like.

The guide member 26 is provided with a central opening 34 in which the upper ends of the plurality of contact pins 27 are disposed at the center. At a plurality of positions, specifically at four corners, a guide surface 35 and a placement surface 36 corresponding to the outer circumferential shape of the IC package 12 are provided.

The guide surface 35 is formed on a tapered surface so that it expands upwardly and is positioned on the placement surface 36 by guiding the four corners of the IC package 12 received from the upper portion, thereby allowing the IC package 12 to be precisely positioned in the accommodating area 18.

In this embodiment, the guide member 26 is provided with an annular portion 20 that continuously surrounds the entire periphery of the side of the accommodating area 18, and the central opening 34, the guide surface 35 and the displacement surface 36 are arrange inside the annular portion 20.

The annular portion 20 includes an annular continuous surface 37 of a continuously annular planar shape at a height spaced upper from the upper surface of the IC package 12 accommodated in the accommodating area 18.

As shown in FIGS. 3-6, the cover unit 22 mounted on the socket body 17 includes an arm 38 pivotally supported on the proximal end side of the socket body 17 and a pad 21 pivotally supported on the distal end side of the arm 38.

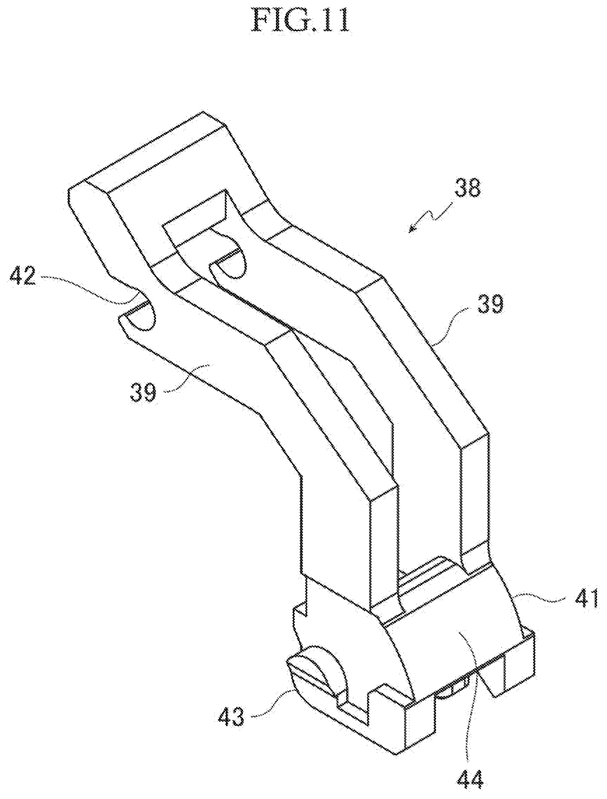

As shown in FIGS. 11 to 13, the arm 38 of the cover unit 22 includes a pivot base portion 41 provided on the proximal end side, a pair of arm pieces 39 protruded parallel to each other from the pivot base portion 41 of V-shaped in the planer view and a pad support portion 42 provided on the distal end side to which the pair of arm pieces 39 are connected.

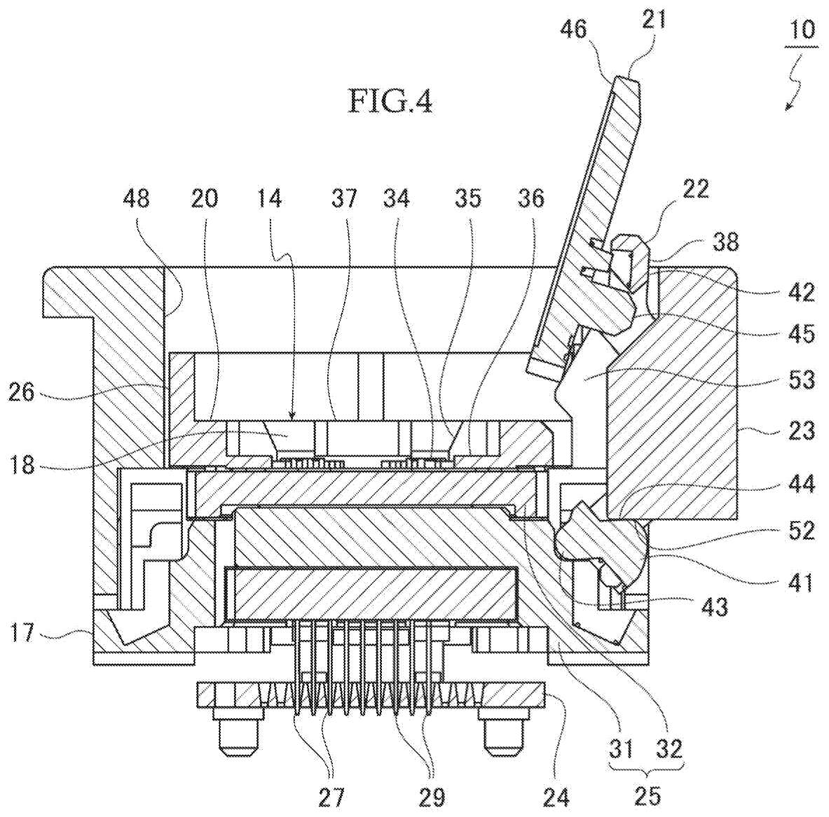

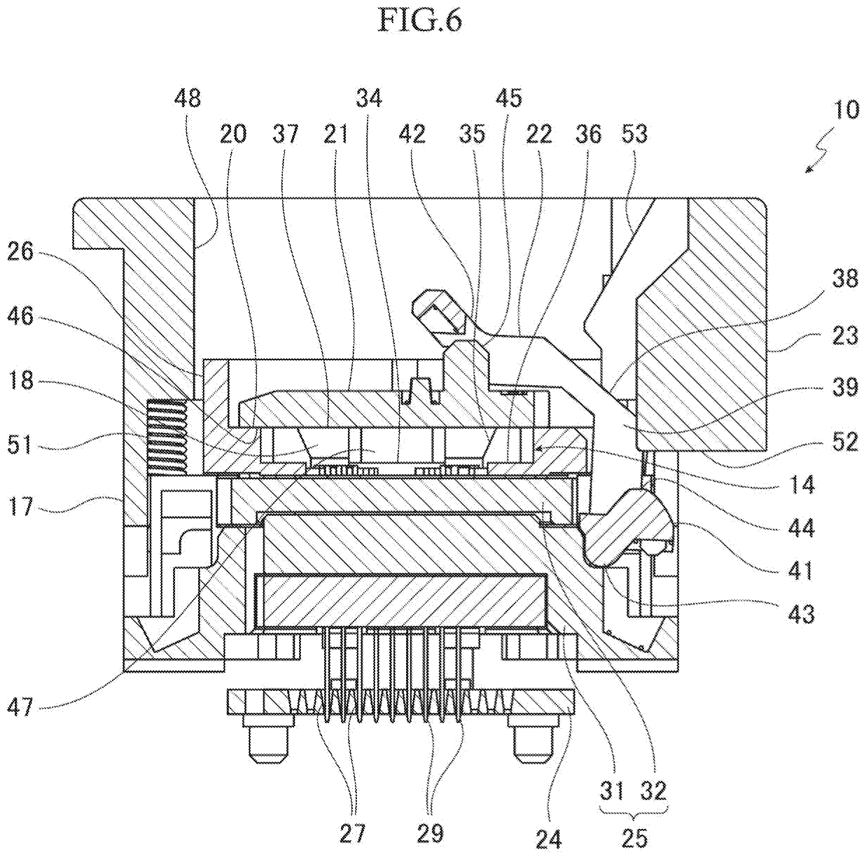

As shown in FIGS. 4 and 6, the pivot base portion 41 includes an arm shaft 43 which is pivotally supported to the fixing block 31 of the socket body 17, and a pushed portion 44 which is protruded from the arm shaft 43 and can be pushed by the operating member 23. The pushed portion 44 is provided horizontally opposite to the pad support portion 42 with respect to the arm shaft 43.

The arm 38 is biased to a rotational direction for closing the pad 21 by a biasing means not shown.

The pad 21 of the cover unit 22 is formed in a substantial plate shape such that the outer shape in the planar view is larger than the inner circumference edge of the IC package 12 accommodated in the socket body 17 and the annular continuous surface 37 of the annular portion 20.

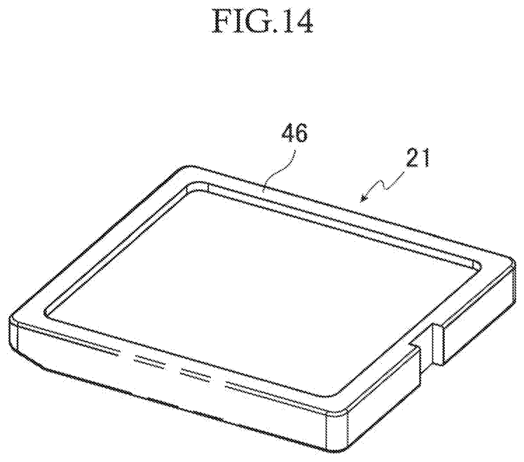

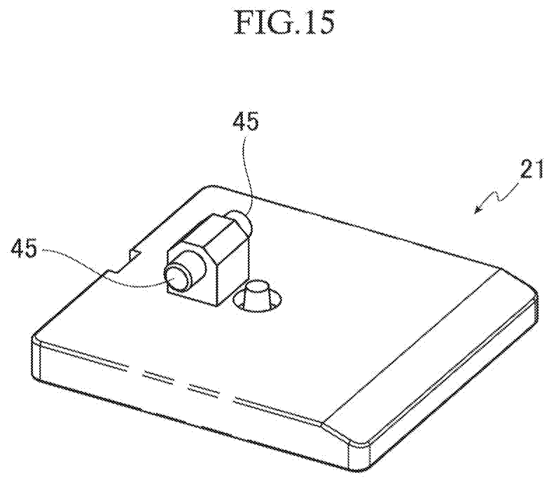

As shown in FIGS. 14 and 15, the surface of the pad 21 of this embodiment is provided with a planar pad abutment surface 46 that is formed concavely and circumferentially contiguously facing to the annular continuous surface 37 of the annular portion 20. The pad abutment surface 46 faces against the annular continuous surface 37 of the guide member 26 so that the pad 21 is positioned at a position spaced from the upper surface of the IC package 12 accommodated in the accommodating area 18 and the accommodating space 47 are internally formed with closing the upper portion of the annular portion 20.

On the back surface, on the protruding position shifted from the center position to the center of rotation of the arm, the pad shaft 45 is provided parallel to the pad abutment surface 46. The pad shaft 45 is rotatably supported on the pad support portion 42 of the arm 38.

As shown in FIGS. 1-6, the operating member 23 mounted on the socket body 17 has a frame shape in which the hollow portion 48 is provided vertically passing through, and are positioned vertically relative to the socket body 17 and upwardly biased relative to the socket body 17 by the biasing means 51. The hollow portion 48 is larger than the shape of the IC package 12 and the pad 21 in planar view.

As shown in FIGS. 3 and 4, a pushing portion 52 is disposed at the lower portion of the operating member 23 in a position where the pushed portion 44 of the arm 38 can be pushed down by lowering of the pushing portion 52. The pushing portion 52 pushes the pushed portion 44 on the opposite side of the pad support 42 of the arm 38 to rotate the arm 38 in the direction of opening the pad 21.

Further, as shown in FIGS. 3 and 4, a pad abutment portion 53, which abuts the back surface of the pad 21 when the arm 38 is rotated and opened, is provided above the side on which the pushing portion 52 of the operating member 23 is disposed. The pad abutment portion 53 is configured to further rotate the pad 21 relative to the arm 38 when the arm 38 rotates in the direction of opening the pad 21 by abutting the back surface of the pad 21 so that the pad 21 is wider opened and positioned outward of the accommodating area 18.

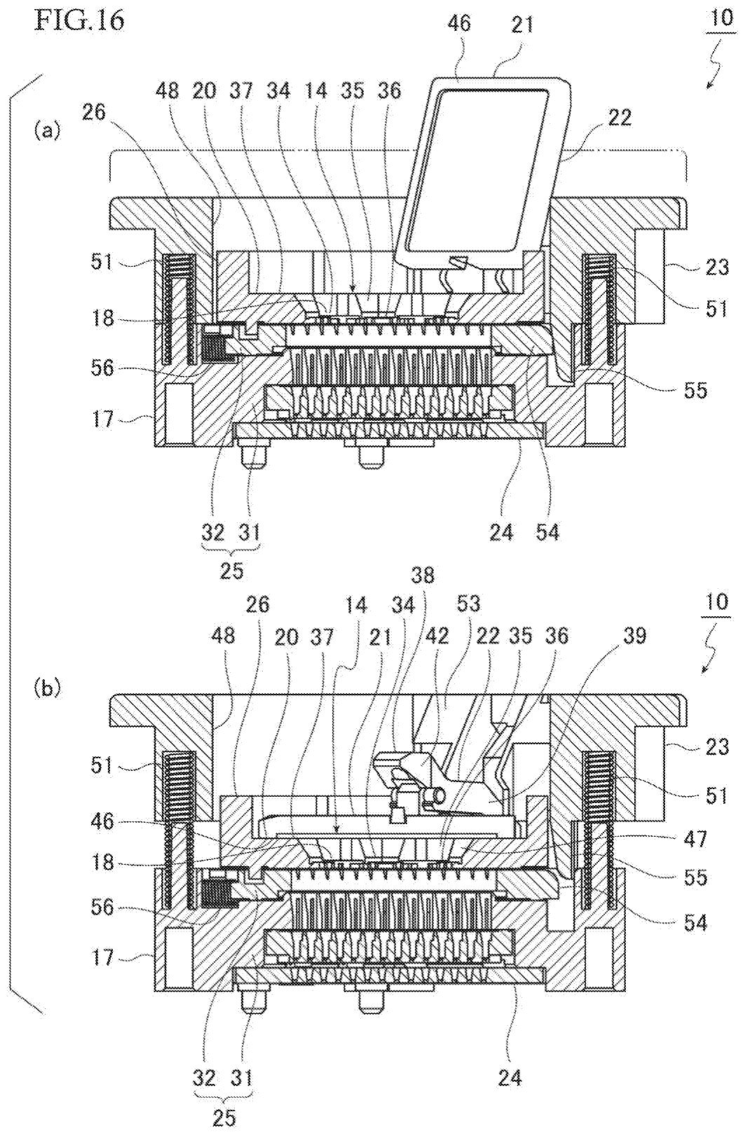

Further, as shown in FIGS. 16(a), (b), a pressing portion 55 for diagonally pressing a pressed portion 54 of the slide plate 32 is provided on one side of the diagonal direction of the IC socket 10 having a substantially square shape in planar view. The slide plate 32 is biased toward one side of the diagonal direction by the biasing means 56. The pressing portion 52 is configured to slide the slide plate 32 against the force of force by pressing the pressed portion 54.

As described above, the slide plate 32 locks one of the pair of clip pieces 28 at each contact pin 27, so that the pair of clip pieces can be opened and closed as shown in FIGS. 8(a), (b) when the slide plate 32 slides in the diagonal direction.

Next, an operation when the IC package 12, as shown in FIG. 17, is accommodated in the IC socket 10 and used will be described.

First, from the state that the operation member 23 is opened and is positioned in the raised position, the operation member 23 is pushed down against the biasing force of the biasing means 51 as shown in FIGS. 3 and 4, and the arm 38 of the cover unit 22 rotates about the arm shaft 43 and the pad 21 opens.

When the operating member 23 is further lowered, the arm 38 further rotates so that the back surface of the pad 21 abuts the pad abutment portion 53 of the operating member 23. Thereby, the pad 21 further rotates toward the direction of further opening with respect to the arm 38 and the pad 21 is disposed outside of the upper portion above the accommodating area 18 and, and the housing portion 14 takes the open state (hereinafter referred to as the “open state”).

Further, as illustrated in FIG. 16(a), when the operation member 23 is lowered, the pressed portion 54 of the slide plate 32 is pressed to the diagonal direction by the pressing portion 55 to slide against the biasing force of the biasing means 56. Thereby, each upper end of the plurality of contact pins 27 opens, respectively, as shown in FIG. 8(b).

In this state, as shown in FIGS. 3 and 4, the IC package 12 is inserted from above into the inside of the guide surface 35 of the guide member 26 through the hollow portion 48 of the operation member 23 and mounted on the placement surface 36. This allows the IC package 12 to be precisely positioned in the accommodating area 18, and each of the solder balls 13 arranged in a matrix shape is disposed between the clip pieces 28 of the contact pin 27.

After the IC package 12 is housed in the housing portion 14, the pressure of the operating member 23 is released to raise the operating member 23. Then, as shown in FIG. 16(b), the slide plate 32 slides to the original position by the biasing force of the biasing means 51. As shown in FIG. 8(a), each pair of the clip pieces 28 of the contact pin 27 is closed and each of the solder balls 13 is clipped between the clip pieces 28.

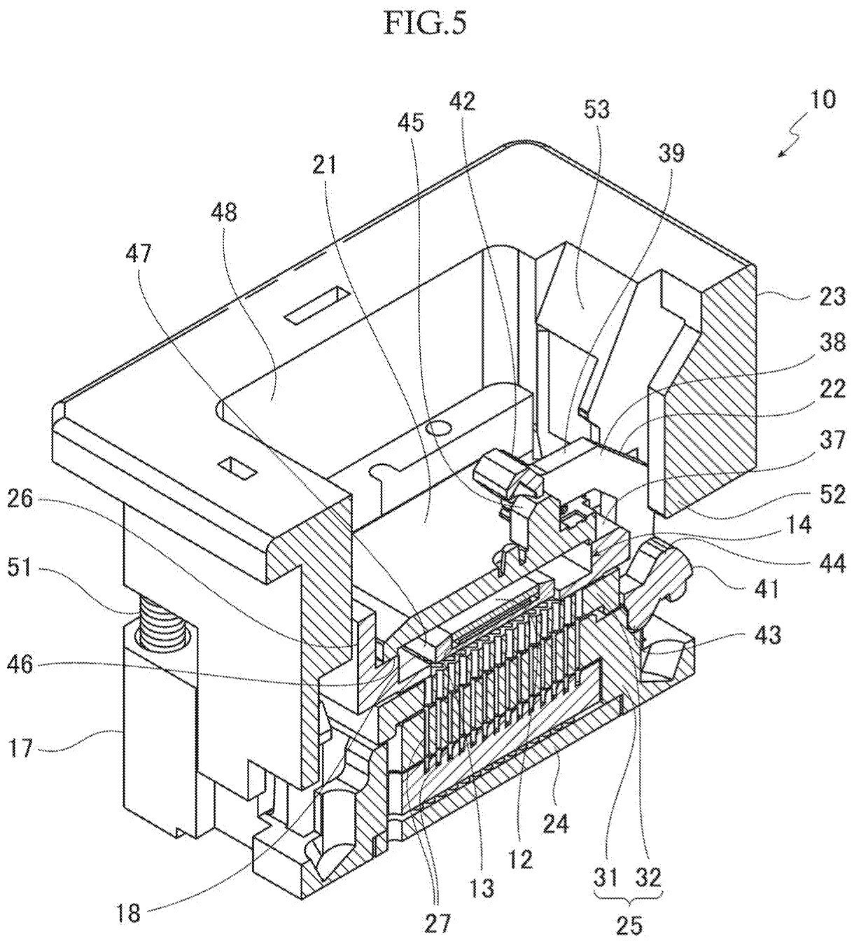

Further, by raising the operating member 23, as shown in FIGS. 5 and 6, the arm 38 of the cover unit 22 rotates about the arm shaft 43 in the direction that the pad 21 closes. The pad abutment surface 46 formed on the back surface of the pad 21 thereby abuts the annular continuous surface 37 formed on the guide member 26. The pad 21 is spaced upwardly from the upper surface of the IC package 12 accommodated in the accommodating space 47.

At this time, since the arm 38 is biased in the closing direction, the pad 21 is abutted against the annular portion 20 of the guide member 26 with sufficient pressure. When the pad 21 is closed and abuts the annular continuous surface 37, the accommodating space 47 closed for the IC package 12 is formed on the housing portion 14, and the IC package 12 is positioned in a predetermined position therein.

Then, for example, a conductive test such as a burn-in test is performed on the IC package 12.

According to the IC socket 10 of this embodiment, the housing portion 14 for the IC package 12 is provided with the annular portion 20 surrounding the side periphery of the accommodating area 18, and the accommodating space 47, which is configured to be closed in the housing portion 14, is formed when the pad 21 is closed and abuts the annular portion 14. Therefore, when the IC package is housed in the IC socket 10 and used, it is possible to prevent foreign matter from being attached to the upper surface of the IC package if the IC package is accommodated in the accommodating space 47 and the pad 21 is closed.

Furthermore, since the pad 21 is spaced upwardly from the upper surface of the IC package 12 by abutting the annular portion 20, the pad 21 does not come into direct contact with the upper surface of the IC package 12 accommodated. Therefore, even if the IC package 12 has a different configuration on the upper surface, if the IC package 12 can be accommodated in the accommodating space 47 and connected to the contact pins 27, the pad 21 can be commonly used to make it difficult to attach foreign matter regardless of the shape of the upper surface.

In a significant case, the housing portion 14 can be commonly used to accommodate the IC package 12 having a different configuration on the upper surface in the housing portion 14 and to use the IC socket 10. For example, when the specifications of the IC package 12 to be accommodated are changed, the IC socket 10 may be used without changing the configuration of the housing portion 14.

Furthermore, since the pad 21 is spaced from the upper surface of the IC package 12, it can be ensured to prevent the pad 21 from contacting the upper surface of the IC package 12. For example, even in the case that the IC package 12 would be shifted in its position, the pad 21 can be prevented from contacted.

Further, according to the IC socket 10 of this embodiment, since the annular portion 20 is a part of the guide member 26 which guides the IC package 12 to the accommodating area 18, it is not necessary to construct the annular portion 20 by further another member, so that the structure of the IC socket 10 which has the pad 21 to form the accommodating space 47 can be simplified.

Furthermore, when the guide member 26 for guiding the IC package 12 to the accommodating area 18 is precisely formed and it is the annular portion 20, the shape of the abutment portion with the pad 21 can also be precisely formed and the accommodating space 47, which can be securely closed, can be easily formed.

Further, according to the IC socket 10 of this embodiment, the cover unit 22 having the arm 38 rotatably supported on the socket body 17 is provided, and the pad 21 is rotatably supported on the arm 22. Therefore, the pad 21 can be moved by rotating the arm 38 with respect to the socket body 17, and further the pad 21 can be rotated more than the rotation angle of the arm 38 by rotating the pad 21 with respect to the arm 38, so that it is easy to open broadly the upper part above the accommodating area 18 provided in the housing portion 14.

In particular, in the IC socket 10 of this embodiment, since the cover unit 22 places the pad 21 outwardly above the accommodating area 18 by making the back surface of the pad 21 abut with the operating member 23, the structure for opening and closing the pad 21 securely by rotating the pad 21 with respect to the arm 38 can be provided compactly.

Accordingly, the cover unit 22 that is easier to open wider above the accommodating area 18 of the housing portion 14 can be configured in less space above the socket body 17 of the IC socket 10 of an open-top type.

Further, according to the IC socket 10 of this embodiment, since the contact pin 27 is opened and closed by the up and down movement of the operating member 23, the opening and closing of the accommodating space 47 by the pad 21 can be linked with the opening and closing of the contact pin 27. Accordingly, while the IC package 12 is accommodated in the accommodating space 47 and connected to the contact pin 27, the accommodating space 47 can be securely closed, and foreign matter can be securely difficult to be attached to the IC package 12 during use of the IC socket 10.

It should be noted that the above-described embodiment may be modified from time to time within the scope of the present invention. For example, in the above-described embodiment, an example of a flat or slightly concave shape of the surface of the pad 21 facing the accommodating area 18 has been described, but is not particularly limited, but may be of a corresponding shape such that the pad 21 and the annular portion 20 may close the entire periphery of the accommodating space 47.

For example, the surface of the pad 21 facing the accommodating area may have a largely concave shape and may provide a space in the recess of the surface of the pad 21 to accommodate the IC package 12. In that case, the annular portion 20 may be formed of a flat area provided on the outer periphery of the accommodating area 18.

In addition, although the above-described embodiment described an example in which the pad 21 in an open state comes into contact with the pad abutment portion 53 provided in the operating member 23, it is possible to provide a pad abutment portion in the socket body 17 to come into contact with the pad contact without any difference.

### [Embodiment 2 of Invention]

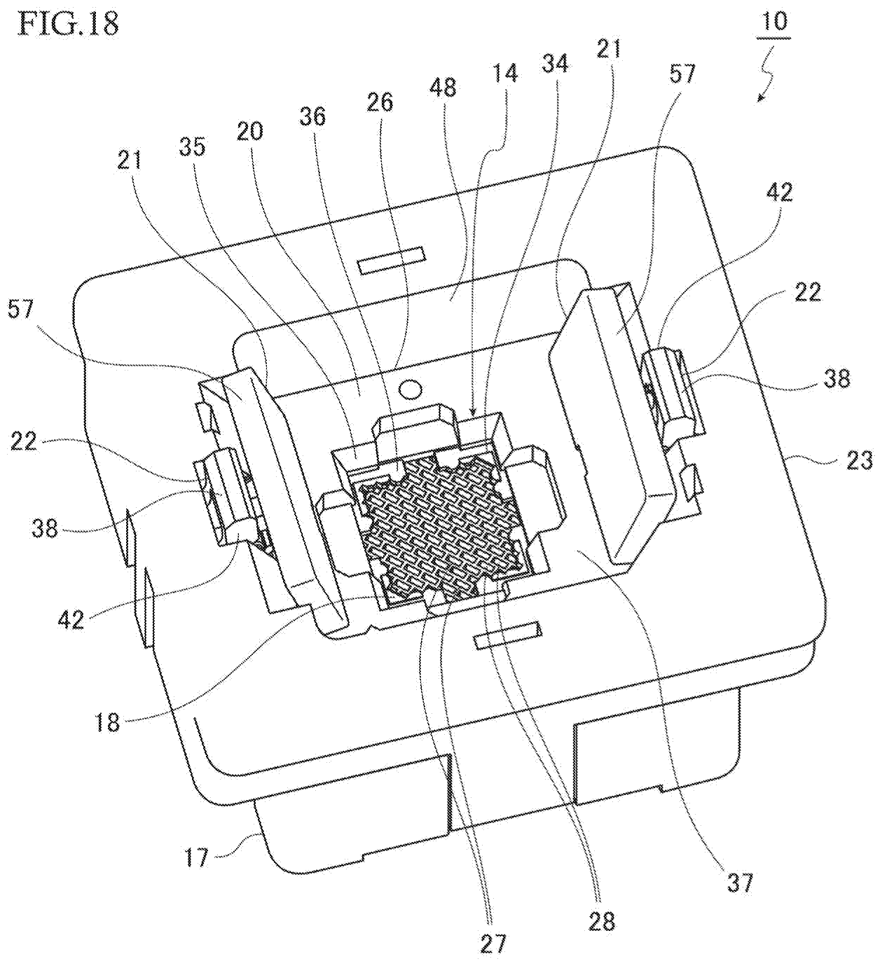

FIGS. 18-21 show embodiment 2 of the present invention. Since this embodiment of the present invention is the same as those of the above-described the embodiment 1 except for the matters described below, the description is omitted except for matters that are different from the above-described the embodiment 1.

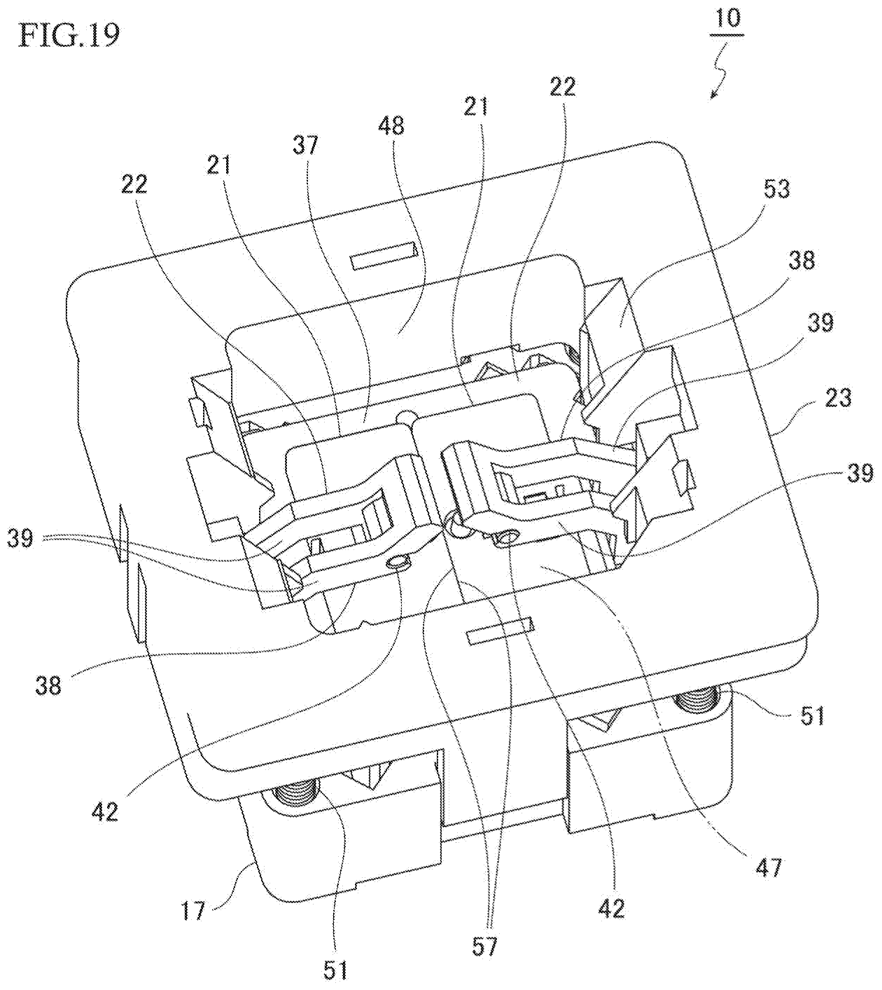

The socket body 17 of the IC socket 10 of this embodiment includes a plurality of pads 21 in different directions, specifically opposite one another, as illustrated in FIGS. 18 and 19. Each pad 21 is rotatably supported at the top of the arm 38 which is pivotally disposed in a position opposite each other.

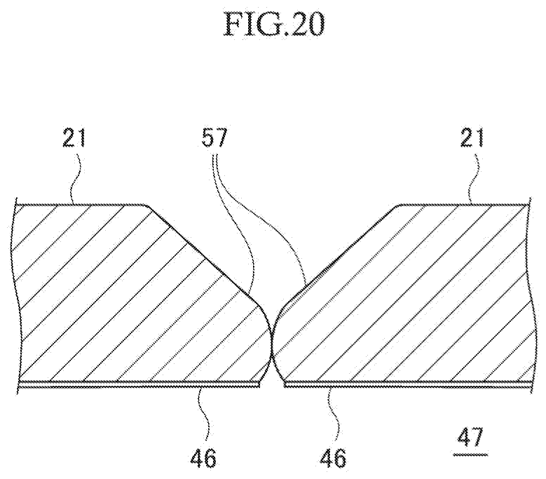

In this embodiment, the tip portions of the pair of pads 21 are provided with opposing contact portions 57 at each end so that when each pad 21 is closed, the tip portions are in close contact with each other over their entire length, as illustrated in FIG. 20.

Others are the same as that of the embodiment 1 of the invention.

Even in this IC socket 10, the operation member 23 is operated and the IC package 12 is accommodated in the accommodating area 18 in the open state as shown in FIG. 18. Then, the operation member 23 is released, so that the pair of pads 21 as shown in FIG. 19 is closed, and foreign matter is suppressed to be adhered to the upper surface of the IC package 12. Thus, the IC socket 10 can be used in the same manner as the embodiment 1 of the invention.

The IC socket 10 of the embodiment 2 of the invention as described above may have the same effect as that of the embodiment 1 of the invention.

Furthermore, in this embodiment, as shown in FIG. 20, the plurality of pads 21 which are opened and closed in different directions are closed so as to contact the annular portion 20 and to close the accommodating space 47. Accordingly, the operating range of each pad 21 can be reduced to make it easy to open and close, and the IC package 12 can be easily taken in and taken out.

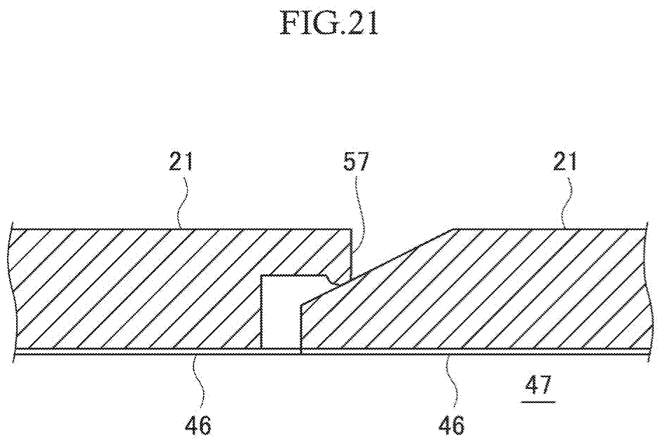

Furthermore, the IC socket 10 according to the embodiment 2 of the present invention may be modified accordingly within the scope of the present invention. For example, as shown in FIG. 21, a contact portion 57 protruding from the lower surface of one of the tip portions of a pair of pads 21 may be provided in a continuous fashion so that the tip portions contact each other over the entire length when each of the pads 21 is closed, and a contact portion 57 may be provided on the upper surface of the other tip portion.

Furthermore, like the embodiment 1 of the invention, each part may be modified from time to time within the scope of the invention.

### EXPLANATION OF REFERENCE

10 IC socket
11 wiring substrate
12 IC package
13 solder ball
14 housing portion
15 image sensor
16 inclined surface
17 socket body
18 accommodating area
20 annular portion
21 pad
22 cover unit
23 operation member
24 base portion
25 contact module
26 guide member
27 contact pin
28 clip piece
29 contact portion
31 fixing block
32 slide plate
33 locking protrusion
34 central opening
35 guide surface
36 placement surface
37 annular continuous surface
38 arm
39 arm piece
41 pivot base portion
42 pad support portion
43 arm shaft
44 pushed portion
45 pad shaft
46 pad abutment surface
47 accommodating space
48 hollow portion
51 biasing means
52 pushing portion
53 pad abutment portion
54 pressed portion
55 pressing portion
56 biasing means
57 contact portion

1. A socket for electrical component comprising: a socket body having a housing portion for accommodating an electrical component; a contact pin configured to be electrically connected to a terminal of the electrical component; an operating member provided movably up and down on the socket body; and a pad which is opened and closed by an up and down movement of the operating member and covers an upper side of the electrical component in a closed state,
wherein the housing portion is provided with an annular portion surrounding a side periphery of an accommodating area for the electrical component,
an accommodating space, which is configured to be closed in the housing portion, for the electric component is formed when the pad is closed and abuts the annular portion, and
the pad is configured to be spaced upwardly from an upper surface of the electrical component that which is accommodated in the accommodating space when the pad is closed and abuts the annular portion.

2. The socket for electrical component according to claim 1, wherein the annular portion is a part of a guide member which is provided in the socket body for guiding the electrical component to the accommodating area.

3. The socket for electrical component according to claim 1, wherein a cover unit having an arm rotatably supported on the socket body is provided, and the pad is rotatably supported on the arm.

4. The socket for electrical component according to claim 3, wherein the cover unit places the pad outwardly above the accommodating area by making a back surface of the pad abut with the socket body or the operating member.

5. The socket for electrical component according to claim 1, wherein the contact pin is opened and closed by the up and down movement of the operating member.

6. The socket for electrical component according to claim 1, wherein a plurality of the pads which open and close in different directions each other are provided, and the accommodating space is closed when the plurality of the pads are closed and abut the annular portion.
